(19) United States
(12) Patent Application Publication
(10) Pub. No.: US 2007/0067123 A1
(43) Pub. Date: Mar. 22, 2007

(54) Advanced arbitrary waveform generator

(76) Inventor: Roger L. Jungerman, Petaluma, CA (US)

Correspondence Address: AGILENT TECHNOLOGIES, INC.;Legal Department, DL 429, Intellectual Property Administration, P.O. Box 7599, Loveland, CO, 80537-0599, US

(21) Appl. No.: 11/231,223

(22) Filed: Sep. 19, 2005

(51) Int. Cl. G01R 13/02

(52) U.S. Cl. 702/67

(57) ABSTRACT

An advanced arbitrary waveform generator (“AAWG”) for producing an arbitrary waveform is disclosed. The AAWG may include a direct digital synthesis (“DDS”) module in signal communication with a sequence memory and a multiplication module in signal communication with both the DDS module and a waveform memory, where the multiplication module receives signal waveform data from the waveform memory and multiplies the received signal waveform data with a DDS output signal to produce the arbitrary waveform signal.

### BACKGROUND OF THE INVENTION

Scientists and engineers who develop and test automotive electronics, avionics, radar, frequency agile, satellite, communication systems and other similar systems often need to measure and simulate components that generate or utilize signal waveforms, or both. In order to produce these signal waveforms, test or measurement systems, or both, usually utilize devices known as arbitrary waveform generators (“AWGs”). As shown in FIG. 1, an AWG 100 is utilized to produce a varying output signal 102 (also referred to as the “signal waveform” from the AWG 100), often in response to an externally supplied trigger signal 104. Generally, AWGs differ from devices such as function generators because AWGs are able to recreate signal waveforms having virtually any waveshape. In general, an arbitrary signal waveform may be defined as a set of digital values with respect to time that are ‘replayed’ through a digital-to-analog converter (“DAC” or “D/A”) to provide the analogue output signal.

Unlike a linear signal waveform that is defined by an equation with a linear slope, an arbitrary signal waveform is a user-defined signal waveform that is specified point-by-point. Usually, the AWG 100 is able to replay the signal waveform at a wide range of repetition rates and at a wide range of amplitudes. The AWG 100 may also be able to modulate the signal waveform in a variety of ways. Generally, an arbitrary signal waveform may be of any shape within the restrictions of the hardware that is generating the signal waveform. These restrictions may include horizontal and vertical resolutions and the clock update rate. Since arbitrary signal waveforms are defined point-by-point, the more update points that define the signal waveform, the higher the resolution of the output signal.

As such, AWGs allow scientists and engineers to produce arbitrary, and at times unique, signal waveforms that may be specific to their applications. These arbitrary signal waveforms may be utilized to simulate “real world” signals that include glitches, drift, noise and other anomalies on an arbitrary signal waveform that a component, such as a device under test (“DUT”), will encounter when it leaves the laboratory or manufacturing floor. As a result, AWGs are utilized in a wide variety of applications across multiple industries such as radar simulations, satellite communications, frequency agile simulations, transducer simulations, disk drive testing, serial data communication, intermediate frequency (“IF”) modulation testing, anti-lock braking, and engine control.

Unfortunately, while it is typically possible to create any desired signal waveform output by programming the sample points in the waveform memory of known AWGs, the lengths of the signal waveforms are limited by the size of the waveform memory. As an example, at a sampling rate of 1.25 giga samples per second (“GS/s”), an AWG memory of 16 mega samples (“MSamples”) produces an analog signal waveform 12.8 milliseconds (“ms”) long.

Attempts to overcome the size limitations of the waveform memory have included utilizing sequencers to control the playback of the generated signal waveforms from the waveform memory. Generally, if the desired signal waveform has some repetitive structure, the waveform memory may be compressed in memory size by utilizing a sequencer to repetitively play selected signal waveform segments from the waveform memory. In this example approach, the sequencer may access a separate sequencer memory that includes data that indicates the number of repetitions of each signal waveform segment of waveform memory. Since each signal waveform segment may be many hundreds or even millions of samples long, the replaying of the signal waveform segments multiple times results in reduced waveform memory size requirements. Additionally, a sequencer may also support loop packets that repeat sections of the sequencer memory multiple times.

In FIG. 2, an example of an implementation of a known AWG 200 is shown. The AWG 200 may include a sequencer 202, sequence memory 204, waveform memory 206, and DACs 208 and 210. As an example of operation of the AWG 200, the sequencer 202 may control the playback of signal waveforms segments from the waveform memory 206. The sequencer 202 may utilize the sequencer memory 204 to determine the number of repetitions of each signal waveform segment to playback from the waveform memory 206. The signal waveform segments are then passed to the DACs 208 and 210. It is appreciated by those skilled in the art that the waveform memory 206 may be optionally a complex waveform memory having complex values and therefore utilizing the first DAC 208 to receive in-phase (“I”) values 212 of the complex signal waveform segment while the second DAC 210 receives quadrature (“Q”) values 214 of the complex signal waveform segment. The DACs 208 and 210 then generate corresponding analog signal waveforms 216 and 218 from the complex signal waveform segment.

Unfortunately in many situations the repetitive sequences of the signal waveform segments are very similar, but not identical. In these cases a simple sequencer cannot be utilized to compress the signal waveform. Therefore, a major limitation to this approach is still the size of the waveform memory because once the number of unique signal waveform segments exceeds the total waveform memory size it is not possible to add new signal waveform segments. Moreover, this approach does not allow for programmable modifications to the signal waveform such as frequency, phase shifts, or gain changes.

Therefore, there is a need to a system and method that allows an AWG to produce signal waveforms that are modifiable without increasing the size requirements of either the waveform memory or sequencer memory.

### SUMMARY

An advanced arbitrary waveform generator (“AAWG”) for producing an arbitrary waveform signal is disclosed. The AAWG includes a sequence memory, sequencer, and waveform memory. The AAWG may also include a direct digital synthesis (“DDS”) module in signal communication with the sequence memory and a multiplication module in signal communication with both the DDS module and waveform memory. The DDS module may receive control data from the sequence memory and, in response, produces a DDS output signal. The multiplication module may receive signal waveform data from the waveform memory and may multiply the received signal waveform data with the DDS output signal to produce the arbitrary waveform signal. Additionally, the waveform memory may produce the signal waveform data in response to receiving a signal waveform address from the sequencer.

In an example of operation, the AAWG may produce the DDS output signal at the DDS module in response to receiving phase, frequency start, and frequency stop data from the sequence memory. The AAWG may then multiply the DDS output signal with signal waveform data from the waveform memory with the multiplication module to produce the arbitrary waveform signal. Again, the waveform memory may produce the signal waveform data in response to receiving a waveform address from the sequencer.

Other systems, methods and features of the invention will be or will become apparent to one with skill in the art upon examination of the following figures and detailed description. It is intended that all such additional systems, methods, features and advantages be included within this description, be within the scope of the invention, and be protected by the accompanying claims.

### BRIEF DESCRIPTION OF THE DRAWINGS

The invention can be better understood with reference to the following figures. The components in the figures are not necessarily to scale, emphasis instead being placed upon illustrating the principles of the invention. In the figures, like reference numerals designate corresponding parts throughout the different views.

FIG. 1 illustrates a block diagram of a known example implementation of an arbitrary waveform generator (“AWG”).

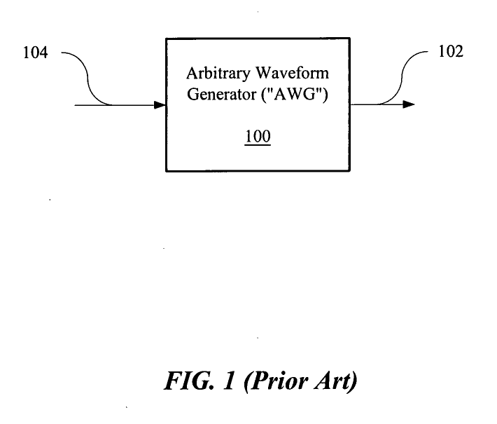

FIG. 2 illustrates a block diagram of another known example implementation of an AWG.

FIG. 3 illustrates a block diagram of an example implementation of an advanced arbitrary waveform generator (“AAWG”) in accordance with the invention.

FIG. 4 illustrates a block diagram of an example of implementation of the DDS module shown in FIG. 3.

FIG. 5 illustrates a relationship between a scenario table, sequence memory, and waveform memory shown in FIG. 3.

FIG. 6 illustrates a block diagram of another example implementation of an AAWG in accordance with the invention.

FIG. 7 illustrates a flow chart of the process performed by the AAWG shown in FIG. 3

### DETAILED DESCRIPTION

In the following description of the preferred embodiment, reference is made to the accompanying drawings that form a part hereof, and which show, by way of illustration, a specific embodiment in which the invention may be practiced. Other embodiments may be utilized and structural changes may be made without departing from the scope of the present invention.

Disclosed in this application is a way to extend an intuitive scenario based arbitrary waveform generator (“AWG”) having a sequencer by adding the flexibility to address complicated signal simulation scenarios. Disclosed is a system capable of supporting programmed modifications to the signal waveform, such as frequency, phase shifts, or gain changes.

In general, the invention discloses an advanced arbitrary waveform generator (“AAWG”) and a method for producing an arbitrary waveform signal. The AAWG may have a sequence memory, sequencer, and waveform memory and may include a direct digital synthesis (“DDS”) module in signal communication with the sequence memory and a multiplication module in signal communication with both the DDS module and waveform memory. The DDS module may receive phase, frequency start, and frequency stop data from the sequence memory and, in response, produces a DDS output signal and the multiplication module may receive signal waveform data from the waveform memory and may multiply the received signal waveform data with the DDS output signal to produce the arbitrary waveform signal. Additionally, the waveform memory may produce the signal waveform data in response to receiving a signal waveform address from the sequencer.

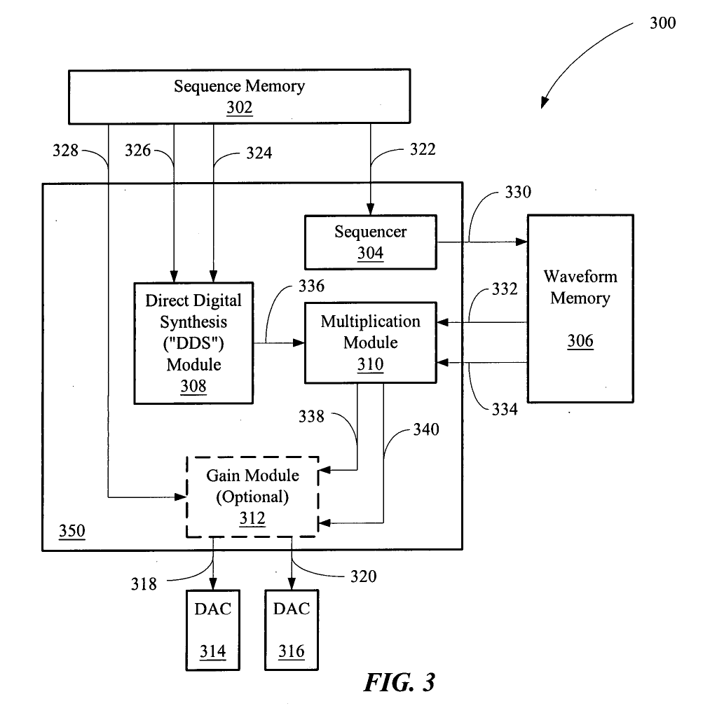

In FIG. 3, a block diagram of an example implementation of an advanced arbitrary waveform generator (“AAWG”) 300, in accordance with the invention, is shown. The AAWG 300 may include a sequence memory 302, sequencer 304, waveform memory 306, DDS module 308, multiplication module 310, and optional gain module 312. The AAWG 300 may also be in signal communication with digital-to-analog converters (“DAC” or “D/A”) 314 and 316 via signal paths 318 and 320, respectively.

As a further example, the sequence memory 302 may include a memory space (not shown) on a storage or memory unit in the AWG 300 that includes pointers to addresses in the waveform memory 306. For the sequencer 304, the contents of the sequencer memory 302 may include the start and stop addresses in the waveform memory 306, together with looping information. Typically the sequence memory 302 is smaller in size than the waveform memory 306 because each sequence entry in the sequence memory 302 points to a number of signal waveform samples in the waveform memory 306. The sequence memory 302 may be implemented utilizing a discrete static random access memory (“SRAM”), dynamic random access memory (“DRAM”), field programmable gate array (“FPGA”) block RAM, or other types of memory technologies. In this implementation example, the sequence memory 302 includes DDS start and stop frequencies, gain start and stop amplitude, and phase offset values. These values are utilized to modify the data pointed to in the stored waveform memory 306 using an internal digital DDS and gain engine (not shown). For example the utilization of the DDS engine may add a Doppler frequency offset to a radar waveform. In this example, the DDS start frequency in the sequence memory 302 represents the initial velocity of the radar target. The DDS stop frequency represents the final Doppler frequency. The linear interpolated DDS frequency represents the instantaneous frequency of the target assuming constant acceleration. Additionally, more complicated acceleration profiles may be created by piecing together several short waveform segments with varying acceleration.

In this example, the sequence memory 302 may be in signal communication with the sequencer 304, DDS module 308, and optional gain module 312 via signal paths 322, 324, 326, and 328. The sequencer 304 may also be in signal communication with the waveform memory 306 via signal path 330. Additionally, the multiplication module 310 may be in signal communication with the waveform memory 306, DDS module 308, and optional gain module 312 via signal paths 332, 334, 336, 338, and 340, respectively.

In an example of operation of the AAWG 300, the sequence memory 302 produces waveform address start and stop markers and passes them to the sequencer 304 via signal path 322. In response, the sequencer 304 passes the waveform address to the waveform memory 306 via signal path 330, which produces waveform data in response to receiving a waveform address from the sequencer 304. Additionally, the sequence memory 302 produces control data (such as, for example, phase start and stop markers and frequency start and stop markers) that is passed to the DDS module 308 via signal paths 326 and 324, respectively. It is appreciated that the control data may be passed from the sequence memory 302 to the DDS module 308 via a control data signal. This control data signal may include sub-control signals that may be passed via the individual signal paths 326 (for the phase start and stop markers) and 324 (for the frequency start and stop markers) or via a single signal path (not shown) from sequence memory 302 to the DDS module 308 based on the choice of implementation of AAWG 300. The multiplication module 310 then receives the complex waveform data as in-phase (“I”) and quadrature-phase (“Q”) data from the waveform memory 306, via signal paths 334 and 332, respectively, and a DDS carrier signal produced by the DDS module via signal path 336. In response, the multiplication module 310 multiples the received DDS output signal (which is the DDS carrier signal and may be complex) from the DDS module with the complex waveform data from the waveform memory 306 to produce a complex arbitrary waveform signal that is passed to the optional gain module 312 via I and Q signal paths 338 and 340, respectively. The optional gain module 312 also receives amplitude start and stop markers from the sequence memory 302, via signal path 328, and utilizes them to either amplify or attenuate the received complex arbitrary waveform signal. The resultant complex signal is passed to the DACs 314 and 316.

As a further example, the sequence memory 302 may include a memory space on a storage or memory unit in the AAWG 300 that includes pointers to addresses in the waveform memory 306. For the sequencer 304 the contents of the sequencer memory 302 may include the start and stop addresses in the waveform memory 306, together with looping information. Typically the sequence memory 302 is smaller in size than the waveform memory 306 because each sequence entry in the sequence memory 302 points to a number of signal waveform samples in the waveform memory 306. The sequence memory 302 may be implemented utilizing a discrete SRAM, DRAM, FPGA, block RAM, or other types of memory technologies. In this implementation example, the sequence memory 302 includes DDS start and stop frequencies, gain start and stop amplitude, and phase offset values. These values are utilized to modify the data pointed to in the stored waveform memory 306 using the internal digital DDS and gain engine as described above.

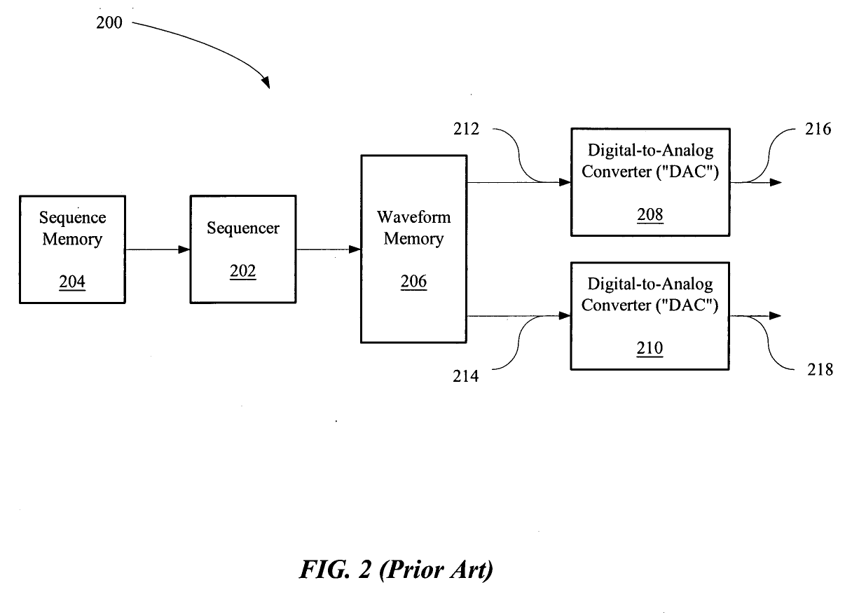

The waveform memory 306 may include of a series of complex samples of I and Q amplitude data. In previous known AWGs, such as the AWG 200 shown in FIG. 2, these values were output directly to I and Q DACs 208 and 210 where they were typically up-converted to a microwave carrier using an I/Q modulator (not shown). However, in the AAWG 300, the I and Q amplitude data are modified by digital circuitry, which includes the DDS module 308 and optional gain module 312, in the digital hardware of the AAWG 300 to provide modified I and Q values based on high-level frequency, gain, and phase offset information stored in the sequencer memory 302. This results in more efficient utilization of the waveform memory 306 and greatly extends the play time of a given signal waveform segment by effectively “compressing” the signal waveform data. Similar to the sequence memory 302, the waveform memory 306 may be also implemented utilizing SRAM, DRAM, FPGA block RAM, or other types of memory technologies.

The sequencer 304 may be a state machine in the digital hardware of the AAWG 300 that successively reads sample data in the waveform memory 306 and routes it to the DACs 314 and 316. The sequencer 304 may loop (i.e., repeat) waveform segments and determine the order in which they are played based on information stored in the sequencer memory 302. The sequencer 304 may step through the sequencer memory 302 as directed by a scenario table (not shown), software control, external triggers, or combination of the three, to dynamically modify the aggregate output waveform being played. The sequencer 304 may also apply DDS frequency offsets and variable gain, and phase offset based on additional information stored in the sequencer memory 302.

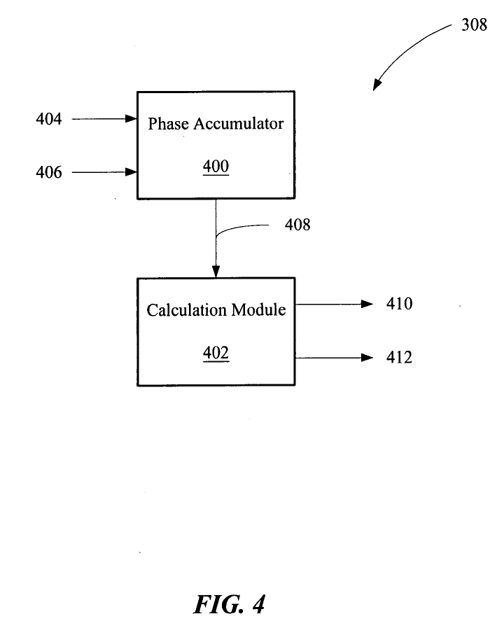

In FIG. 4, a block diagram of an example of an implementation of the DDS module 308 of FIG. 3 is shown. The DDS module 308 may include a phase accumulator 400 and calculation module 402. The phase accumulator 400 may be set to an initial value by a phase offset argument which is stored in the sequence memory 302. This initial value 404 may be incremented each clock cycle 406 by a value that corresponds the desired output frequency (radians of phase per clock cycle), where the calculations are typically performed in integer format. The phase accumulator 400 then passes the incremented values to the calculation module via signal path 408. The phase values may be converted to the I and Q local oscillator (“LO”) outputs 410 and 412 by sine and cosine calculation in a calculation module 402 typically utilizing look-up tables (not shown). The DDS module 308 often operates at a sub-multiple of the sample clock rate. In this case the implementation is poly-phase, with several I and Q outputs 410 and 412 being calculated in parallel for each clock cycle. It is appreciated by those skilled in the art that if DDS module 308 is a complex DDS module the DDS output 336 will be a complex signal having I and Q components that correspond to I and Q outputs 410 and 412. The DDS module 308 may be implemented utilizing an FPGA, an application specific integrated circuit (“ASIC”), digital signal processor (“DSP”), or in software.

It is appreciated that the AAWG 300 may be implemented either partially or completely in one integrated circuit (“IC”) 350 or in software. The IC may be an FPGA, DSP, or ASIC.

In another example, the AAWG may be implemented utilizing only one memory. In this case, the signal waveform data is stored only in a single waveform memory (not shown). The signal waveform data may include either amplitude envelope data or amplitude envelope multiplied by a carrier data. Therefore, the signal waveform is output directly to a single DAC (not shown). In this case the AAWG would not need a DDS module or a multiplication module to produce the arbitrary waveform signal.

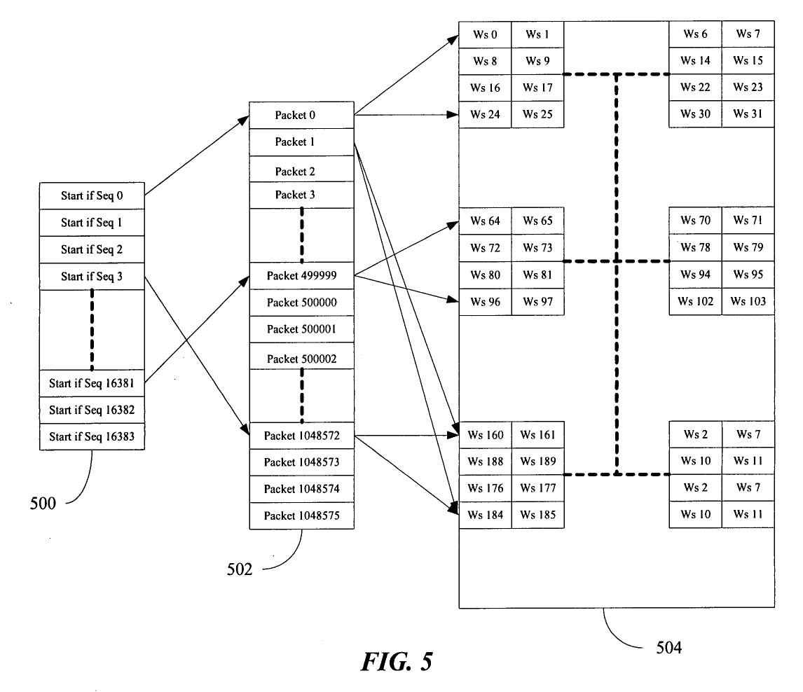

In FIG. 5, a relationship between a scenario table 500, sequence memory 502, and waveform memory 504 is shown. The scenario table 500 points to particular sets of packets in the sequence memory 502 shown for example as Packet0, Packet1, . . . Packet 1048575. Each scenario (shown as Seq 0, Seq 1, . . . . Seq 16383) typically represents a different type of signal waveform that the user may want to play. For example, one scenario might be a carrier wave (“CW”) tone while another may be a more complicated pulsed chirped radar signal. Each packet in the sequence memory 502 includes a start and stop address pointer to the waveform memory 504, where the actual signal waveform samples are stored. The packet also has the ability to repeat a particular set of signal waveform data specified a number of times where the signal waveform data is located within the waveform memory 504. It is appreciated that generally the waveform memory 504 is accessed at a lower rate than the sample clock (not shown) of the DAC (not shown), therefore several waveform samples may be read in parallel on each clock cycle. In the example shown in FIG. 5, the signal waveform data is read eight samples at a time. In the AAWG 300, the packet information in the sequence memory 502 may be augmented to include the DDS frequency and phase values as well as the gain term. These values are utilized to modify the signal waveform data, within the waveform memory 504, as the signal waveform data is read. In this way the same signal waveform data may be utilized to generate several different scenarios, as defined by the scenario table 500, by varying the supplemental data (DDS and gain) in the sequence memory 502.

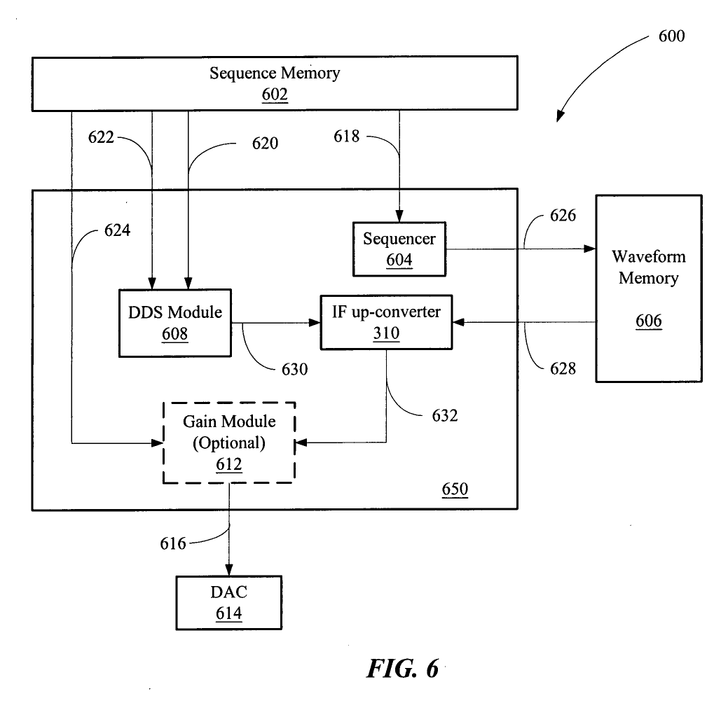

FIG. 6 illustrates a block diagram of another example implementation of an AAWG 600 in accordance with the invention. The implementation example of the AAWG 600 is similar to the implementation example of the AAWG 300 shown in FIG. 3, except that the AAWG 600 utilizes real values rather than complex values and may be described as a digital IF up-conversation example in contrast to the I and Q up-conversation example of FIG. 3.

In FIG. 6, the AAWG 600 may include a sequence memory 602, sequencer 604, waveform memory 606, DDS module 608, IF up-converter module 310, and optional gain module 612. The AAWG 300 may also be in signal communication with a DAC 614 via signal path 616.

As a further example, the sequence memory 602 may include a memory space (not shown) on a storage or memory unit in the AWG 600 that includes pointers to addresses in the waveform memory 606. For the sequencer 604, the contents of the sequencer memory 602 may include the start and stop addresses in the waveform memory 606, together with looping information. Typically the sequence memory 602 is smaller in size than the waveform memory 606 because each sequence entry in the sequence memory 602 points to a number of signal waveform samples in the waveform memory 606. Again, the sequence memory 602 may be implemented utilizing a SRAM, DRAM, FPGA, block RAM, or other types of memory technologies. In this implementation example, the sequence memory 602 includes control data such as DDS start and stop frequencies, gain start and stop amplitude, and phase offset values. The control data is utilized to modify the data pointed to in the stored waveform memory 606 using an internal digital DDS and gain engine (not shown). Again, the utilization of the DDS engine may add a Doppler frequency offset to a radar waveform where the DDS start frequency in the sequence memory 602 represents the initial velocity of the radar target. The DDS stop frequency represents the final Doppler frequency. The linear interpolated DDS frequency represents the instantaneous frequency of the target assuming constant acceleration. Additional acceleration profiles may be created by piecing together several short waveform segments with varying acceleration.

In this example, the sequence memory 602 may be in signal communication with the sequencer 604, DDS module 608, and optional gain module 612 via signal paths 618, 620, 622, and 624. The sequencer 604 may also be in signal communication with the waveform memory 606 via signal path 626. Additionally, the IF up-converter module 610 may be in signal communication with the waveform memory 606, DDS module 608, and optional gain module 612 via signal paths 628, 630, and 632, respectively.

In an example of operation of the AAWG 600, the sequence memory 602 produces waveform address start and stop markers and passes them to the sequencer 604 via signal path 618. In response, the sequencer 604 passes the waveform address to the waveform memory 606 via signal path 626, which produces signal waveform data in response to receiving a waveform address from the sequencer 604. Additionally, the sequence memory 602 produces control data that includes phase start and stop markers and frequency start and stop markers and passes the control data to the DDS module 608 via signal paths 622 and 620, respectively. Again, it is appreciated that the control data may be passed from the sequence memory 602 to the DDS module 608 via a control data signal which may include sub-control signals. The sub-control signals may be passed via the individual signal paths 622 (for the phase start and stop markers) and 620 (for the frequency start and stop markers), respectively, or via a single signal path (not shown) from sequence memory 602 to the DDS module 608 based on the choice of implementation of the AAWG 600. The IF up-converter module 610 then receives the real signal waveform data from the waveform memory 606, via signal path 628, and a DDS carrier signal produced by the DDS module 608 via signal path 630. In response, the IF up-converter 610 up-converts (i.e., multiplies or modulates) the complex waveform data from the waveform memory 606 with the received DDS output signal (which is the DDS carrier signal) from the DDS module to produce an arbitrary waveform signal that is passed to the optional gain module 612 via path 632. The optional gain module 612 also receives amplitude start and stop markers from the sequence memory 602, via signal path 624, and utilizes them to either amplify or attenuate the received complex arbitrary waveform signal. The resultant amplified arbitrary waveform signal is passed to the DAC 614.

As described above as further example, the sequence memory 602 may include a memory space on a storage or memory unit in the AAWG 600 that includes pointers to addresses in the waveform memory 606. For the sequencer 604 the contents of the sequencer memory 602 may include the start and stop addresses in the waveform memory 606, together with looping information. Typically the sequence memory 602 is smaller in size than the waveform memory 606 because each sequence entry in the sequence memory 602 points to a number of signal waveform samples in the waveform memory 606. The sequence memory 602 may be implemented utilizing a discrete SRAM, DRAM, FPGA, block RAM, or other types of memory technologies. In this implementation example, the sequence memory 602 includes DDS start and stop frequencies, gain start and stop amplitude, and phase offset values. These values are utilized to modify the data pointed to in the stored waveform memory 606 using the internal digital DDS and gain engine as described above.

The waveform memory 606 may include a series of samples of real amplitude data where the samples are modified by digital circuitry, which includes the DDS module 608 and optional gain module 612, in the digital hardware of the AAWG 600 to provide modified values based on high-level frequency, gain, and phase offset information stored in the sequencer memory 602. Again, this results in more efficient utilization of the waveform memory 606 and greatly extends the play time of a given signal waveform segment by effectively “compressing” the signal waveform data. Similar to the sequence memory 602, the waveform memory 606 may be also implemented utilizing SRAM, DRAM, FPGA block RAM, or other types of memory technologies.

The sequencer 604 may be a state machine in the digital hardware of the AAWG 600 that successively reads sample data in the waveform memory 606 and routes it to the DAC 614. The sequencer 604 may loop (i.e., repeat) waveform segments and determine the order in which they are played based on information stored in the sequencer memory 602. The sequencer 604 may step through the sequencer memory 602 as directed by a scenario table (not shown), software control, external triggers, or combination of the three, to dynamically modify the aggregate output waveform being played. The sequencer 604 may also apply DDS frequency offsets and variable gain, and phase offset based on additional information stored in the sequencer memory 602.

As described above, the DDS module 608 may include a phase accumulator (not shown) and calculation module (not shown) where the phase accumulator may be set to an initial value by a phase offset argument which is stored in the sequence memory. This initial value may be incremented each clock cycle by a value that corresponds to the desired output frequency (radians of phase per clock cycle), where the calculations are typically performed in integer format. The phase accumulator then passes the incremented values to the calculation module. The phase values may be converted to an LO output by sine and cosine calculation in a calculation module typically utilizing look-up tables (not shown). Again, the DDS module 608 often operates at a sub-multiple of the sample clock rate and may be implemented utilizing an FPGA, ASIC, DSP, or in software.

It is again appreciated that the AAWG 600 may be implemented either partially or completely in one IC 650 or in software. The IC may be an FPGA, DSP, or ASIC.

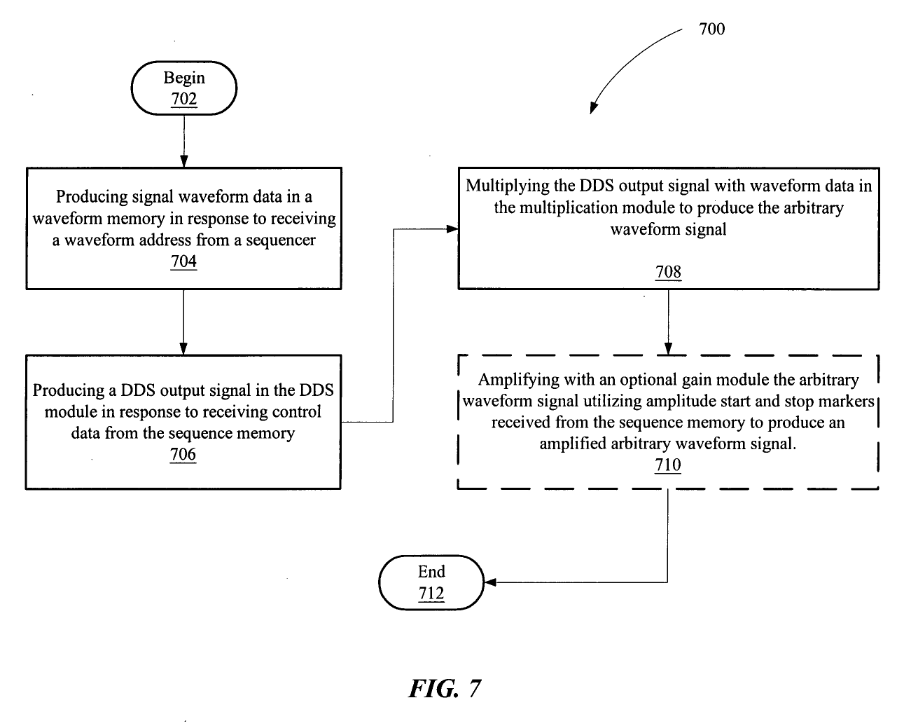

FIG. 7 illustrates a flow chart 700 of the process performed by the AAWG 300 shown in FIG. 3. The process begins 702 in step 704 where the waveform memory 306 produces signal waveform data in response to receiving a waveform address from the sequencer 304. In step 706, the DDS module 308 produces the DDS output signal in response to receiving a control signal, having phase, frequency start, and frequency stop data, from the sequence memory 302. The multiplication module 310 then multiplies the DDS output signal with waveform data to produce the arbitrary waveform signal in step 708. In optional step 710, the optional gain module 312 amplifies the arbitrary waveform signal utilizing amplitude start and stop markers received from the sequence memory 302 to produce the amplified arbitrary waveform signal. The process then ends 712. It is appreciated that order of both steps 704 and 706 may be reversed or performed simultaneously without deviating from the scope of the invention.

Persons skilled in the art will understand and appreciate, that one or more processes, sub-processes, or process steps described may be performed by hardware or software, or both. Additionally, the AAWG may be implemented completely in software that would be executed within a microprocessor, general-purpose processor, combination of processors, DSP, or ASIC. If the process is performed by software, the software may reside in software memory in the controller. The software in software memory may include an ordered listing of executable instructions for implementing logical functions (i.e., “logic” that may be implemented either in digital form such as digital circuitry or source code or in analog form such as analog circuitry or an analog source such an analog electrical, sound or video signal), and may selectively be embodied in any computer-readable (or signal-bearing) medium for use by or in connection with an instruction execution system, apparatus, or device, such as a computer-based system, processor-containing system, or other system that may selectively fetch the instructions from the instruction execution system, apparatus, or device and execute the instructions. In the context of this document, a “machine-readable medium”, “computer-readable medium” or “signal-bearing medium” is any means that may contain, store, communicate, propagate, or transport the program for use by or in connection with the instruction execution system, apparatus, or device. The computer readable medium may selectively be, for example but not limited to, an electronic, magnetic, optical, electromagnetic, infrared, or semiconductor system, apparatus, device, or propagation medium. More specific examples, but nonetheless a non-exhaustive list, of computer-readable media would include the following: an electrical connection (electronic) having one or more wires; a portable computer diskette (magnetic); a RAM (electronic); a read-only memory “ROM” (electronic); an erasable programmable read-only memory (EPROM or Flash memory) (electronic); an optical fiber (optical); and a portable compact disc read-only memory “CDROM” (optical). Note that the computer-readable medium may even be paper or another suitable medium upon which the program is printed, as the program can be electronically captured, via, for instance, optical scanning of the paper or other medium, then compiled, interpreted or otherwise processed in a suitable manner if necessary, and then stored in a computer memory.

It will be understood that the foregoing description of an implementation has been presented for purposes of illustration and description. It is not exhaustive and does not limit the claimed inventions to the precise form disclosed. Modifications and variations are possible in light of the above description or may be acquired from practicing the invention. The claims and their equivalents define the scope of the invention.

What is claimed:

1. An advanced arbitrary waveform generator (“AAWG”) for producing an arbitrary waveform signal, the AAWG having a sequence memory, sequencer, and waveform memory, the AAWG comprising:
a direct digital synthesis (“DDS”) module in signal communication with the sequence memory, where the DDS module receives control data from the sequence memory and, in response, produces a DDS output signal; and
a multiplication module in signal communication with both the DDS module and waveform memory, where the multiplication module receives signal waveform data from the waveform memory and multiplies the received signal waveform data with the DDS output signal to produce the arbitrary waveform signal,
wherein the waveform memory produces the signal waveform data in response to receiving a signal waveform address from the sequencer.

2. The AAWG of claim 1, further including a gain module in signal communication with both the sequence memory and the multiplication module wherein the gain module produces an amplified arbitrary waveform signal.

3. The AAWG of claim 2, wherein the gain module includes a negative gain and the amplified arbitrary waveform signal is less in magnitude than the arbitrary waveform signal.

4. The AAWG of claim 2, wherein the multiplication module is a complex multiplication module.

5. The AAWG of claim 2, wherein the sequence memory and waveform memory are located within the same memory module.

6. The AAWG of claim 5, wherein the memory module is an integrated circuit chosen from a group consisting of a discrete static random access memory, dynamic random access memory, field programmable gate array, and block random access memory.

7. The AAWG of claim 1, wherein the multiplication module is a complex multiplication module.

8. The AAWG of claim 1, wherein the sequence memory and waveform memory are located within the same memory module.

9. The AAWG of claim 1, wherein the sequence memory is an integrated circuit chosen from a group consisting of a discrete static random access memory, dynamic random access memory, field programmable gate array, and block random access memory.

10. The AAWG of claim 1, wherein the waveform memory is an integrated circuit chosen from a group consisting of a discrete static random access memory, dynamic random access memory, field programmable gate array, and block random access memory.

11. The AAWG of claim 1, wherein the sequencer, the DDS module, and multiplication module are integrated into a single integrated circuit (“IC”).

12. The AAWG of claim 11, wherein the IC is chosen from the group consisting of a field programmable gate array, digital signal processor, and application specific integrated circuit.

13. The AAWG of claim 12, wherein the single IC also includes a gain module.

14. The AAWG of claim 1, wherein the sequence memory includes a memory space that includes pointers to addresses in the waveform memory.

15. The AAWG of claim 14, wherein the sequence memory further includes a scenario table that points to particular sets of packets in the sequence memory, wherein each scenario in the scenario table represents a different type of signal waveform.

16. A method for producing an arbitrary waveform signal utilizing an advanced arbitrary waveform generator (“AAWG”), the AWG having a sequence memory, sequencer, and waveform memory, the method comprising:
producing a direct digital synthesis (“DDS”) output signal from a control data signal; and
multiplying the DDS output signal with signal waveform data to produce the arbitrary waveform signal.

17. The method of claim 16, further including amplifying the arbitrary waveform signal to produce an amplified arbitrary waveform signal.

18. The method of claim 17, wherein amplifying includes amplifying with a negative gain and the amplified arbitrary waveform signal is less in magnitude than the arbitrary waveform signal.

19. The method of claim 17, wherein multiplying the DDS output signal with the waveform data includes complex multiplying the DDS output signal with the waveform data.

20. An advanced arbitrary waveform generator (“AAWG”) for producing an arbitrary waveform signal, the AAWG having a sequence memory, a sequencer, a waveform memory, and a signal-bearing medium, the signal-bearing medium comprising:
logic configured for producing a direct digital synthesis (“DDS”) output signal in response to control data from a sequence memory; and
logic configured for multiplying the DDS output signal with signal waveform data to produce the arbitrary waveform signal.
